(19) United States
(12) Patent Application Publication
(10) Pub. No.: US 2025/0024748 A1
(43) Pub. Date: Jan. 16, 2025

(54) PHOTODETECTION DEVICE AND MANUFACTURING METHOD THEREOF

(71) Applicant: Japan Display Inc., Tokyo (JP)

(72) Inventors: Motochika YUKAWA, Tokyo (JP); Isao SUZUMURA, Tokyo (JP); Genki ASOZU, Tokyo (JP)

(73) Assignee: Japan Display Inc., Tokyo (JP)

(21) Appl. No.: 18/770,974

(22) Filed: Jul. 12, 2024

(30) Foreign Application Priority Data
Jul. 14, 2023 (JP) 2023-115764

(51) Int. Cl. H10K 71/60; H10K 30/82; H10K 39/38; H10K 71/00; H10K 71/20; H10K 102/10

(52) U.S. Cl. CPC H10K 71/60; H10K 30/82; H10K 39/38; H10K 71/231; H10K 71/621; H10K 2102/103

(57) ABSTRACT

A photodetection device includes a lower structure, one or more common line connecting portions and one or more pixel electrodes provided on the lower structure, an organic photoelectric conversion layer that is provided so as to overlap with the one or more pixel electrodes and not to overlap with the one or more common line connecting portions, and a transparent electrode layer that is provided so as to overlap with the organic photoelectric conversion layer and the one or more common line connecting portion, where a part of the transparent electrode layer that overlaps with the one or more pixel electrodes is thicker than other parts.

### CROSS-REFERENCE TO RELATED APPLICATION

The present application claims priority from Japanese application No. 2023-115764 filed on Jul. 14, 2023, the content of which is hereby incorporated by reference into this application.

### BACKGROUND OF THE INVENTION

### 1. Field of the Invention

The present invention relates to a photodetection device and a method for manufacturing the photodetection device.

### 2. Description of the Related Art

In recent years, a detection device in which organic photodiodes (OPD) are arranged on a substrate has been known. Such a detection device is used as a biometric sensor for detecting biometric information, such as a fingerprint and a vein.

The detection device using an OPD includes a thin film transistor and an OPD layer that are formed on a substrate. The OPD layer is formed of a plurality of layers, including such as an organic light-receiving layer, disposed between the upper electrode and the lower electrode. For example, JP2021-68793A discloses the detection device in which OPD layers are selectively formed only in the sensor area.

### SUMMARY OF THE INVENTION

The inventors of the present application have studied a step of applying an organic layer to the entire substrate and then patterning the organic layer by dry etching in order to improve the film uniformity of the organic layer. When the organic layer is etched, an inorganic material such as SiN, SiO, and AlOx needs to be provided on the organic layer as a protective layer, because a selectivity cannot be gotten with a typical resist. However, when such a protective layer is removed after the organic layer is etched, the foundation layer formed of the same material as the protective layer disappears at the same time. Further, if a residue of the protective layer is generated on the organic layer, the characteristics of the sensor deteriorate.

One or more embodiments of the present invention have been conceived in view of the above, and an object thereof is to provide a photodetection device that facilitates patterning of organic layers and is improved in quality, and a method for manufacturing the photodetection device.

(1) A manufacturing method of a photodetection device according to the present invention includes forming a lower structure, forming one or more common line connecting portions and one or more pixel electrodes on the lower structure, continuously forming an organic photoelectric conversion layer on the one or more common line connecting portions and the one or more pixel electrodes, forming a first transparent electrode layer continuously on the one or more common line connecting portions and the one or more pixel electrodes, forming a resist on the first transparent electrode layer which is patterned so as to overlap with the one or more pixel electrode and not to overlap with the one or more common line connecting portion, removing a part of the first transparent electrode layer that is not covered with the resist, removing the resist and a part of the organic photoelectric conversion layer that is not covered with the first transparent electrode layer so as to expose the one or more common line connecting portion; and forming a second transparent electrode layer continuously so as to overlap with the organic photoelectric conversion layer or the first transparent electrode layer as well as the one or more common line connecting portion.

(2) In the manufacturing method of the photodetection device according to (1), the second transparent electrode layer may be formed so as to overlap with the first transparent electrode layer and the one or more common line connecting portion.

(3) The manufacturing method of the photodetection device according to (1) may further include removing the first transparent electrode layer after exposing the one or more common line connecting portion, and the second transparent electrode layer may be formed so as to overlap with the organic photoelectric conversion layer and the one or more common line connecting portion.

(4) In the manufacturing method of the photodetection device according to (1), the resist may be formed on the first transparent electrode layer with each of the pixel electrodes so as to overlap a corresponding one of the pixel electrodes.

(5) In the manufacturing method of the photodetection device according to (4), two or more pixel electrodes and one common line connecting portion may be formed, and step may form the second transparent electrode layer may be formed so as to overlap with the organic photoelectric conversion layer or the first transparent electrode layer and the one common line connecting portion.

(6) In the manufacturing method of the photodetection device according to (4), one pixel electrode and one common line connecting portion may be formed so as to be adjacent to each other, and the second transparent electrode layer may be formed so as to overlap with the one pixel electrode and the one common line connecting portion.

(7) The manufacturing method of the photodetection device according to (4) may further include forming a rib so as to cover a side surface of the organic photoelectric conversion layer before forming the second transparent electrode layer and after exposing the one or more common line connecting portion.

(8) In the photodetection device according to any one of (1) to (3), the first transparent electrode layer and the second transparent electrode layer may be formed of a same material.

(9) In the photodetection device according to any one of (1) to (3), the first transparent electrode layer may be made of indium-based oxide.

(10) In the photodetection device according to any one of (1) to (3), the first transparent electrode layer may be made of indium-zinc oxide (IZO).

(11) In the manufacturing method of the photodetection device according to (1), a part of the first transparent electrode layer that is not covered with the resist may be removed by an inductively coupled plasma method using a gas containing CH4.

(12) In the manufacturing method of the photodetection device according to (1), the resist and a part of the organic photoelectric conversion layer that is not covered with the first transparent electrode layer may be removed using an inductively coupled plasma method using a gas containing O2 so as to expose the one or more common line connecting portions.

(13) A photodetection device according to the present invention include a lower structure, one or more common line connecting portions and one or more pixel electrodes provided on the lower structure, an organic photoelectric conversion layer that is provided so as to overlap with the one or more pixel electrodes and not to overlap with the one or more common line connecting portions, and a transparent electrode layer that is provided so as to overlap with the organic photoelectric conversion layer and the one or more common line connecting portion, wherein a part of the transparent electrode layer that overlaps with the one or more pixel electrodes is thicker than other parts.

(14) In the photodetection device according to (13), the transparent electrode layer includes a first transparent electrode layer that is provided on the organic photoelectric conversion layer so as to overlap with the one or more pixel electrode and not to overlap with the one or more common line connecting portion and a second transparent electrode layer that is provided so as to overlap with the first transparent electrode layer and the one or more common line connecting portion.

### BRIEF DESCRIPTION OF THE DRAWINGS

FIG. 1 is a block diagram showing an outline of a substrate configuration of a photodetection device according to the first embodiment;

FIG. 2 is a block diagram showing an outline of a circuit configuration of the photodetection device according to the first embodiment;

FIG. 3 is a cross-sectional view of the photodetection device corresponding to the line III-III in FIG. 1;

FIG. 4A is a cross-sectional view of the photodetection device according to the first embodiment of the present invention showing a manufacturing method thereof;

FIG. 4B is a cross-sectional view of the photodetection device indicating a step subsequent to the step of FIG. 4A;

FIG. 4C is a cross-sectional view of the photodetection device indicating a step subsequent to the step of FIG. 4B;

FIG. 4D is a cross-sectional view of the photodetection device indicating a step subsequent to the step of FIG. 4C;

FIG. 4E is a cross-sectional view of the photodetection device indicating a step subsequent to the step of FIG. 4D;

FIG. 4F is a cross-sectional view of the photodetection device indicating a step subsequent to the step of FIG. 4E;

FIG. 5 is a table indicating an example of etching conditions for forming an OPD layer according to the first embodiment of the present invention;

FIG. 6 is a schematic diagram showing a manufacturing method of the photodetection device according to the second embodiment of the present invention;

FIG. 7 is a schematic diagram indicating a step subsequent to the step of FIG. 6;

FIG. 8 is a schematic diagram showing a manufacturing method of the photodetection device according to the third embodiment of the present invention;

FIG. 9 is a schematic diagram indicating a step subsequent to the step of FIG. 8;

FIG. 10 is a schematic diagram showing a manufacturing method of the photodetection device according to the fourth embodiment of the present invention; and

FIG. 11 is a schematic diagram showing a manufacturing method of the photodetection device according to the fifth embodiment of the present invention.

### DETAILED DESCRIPTION OF THE INVENTION

Embodiments of the present invention will be described in detail referring to the drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the present invention. In this specification and the drawings, some elements identical or similar to those shown previously are denoted by the same reference signs as the previously shown elements, and thus repetitive detailed descriptions of them may be omitted as appropriate.

Further, in the embodiments, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

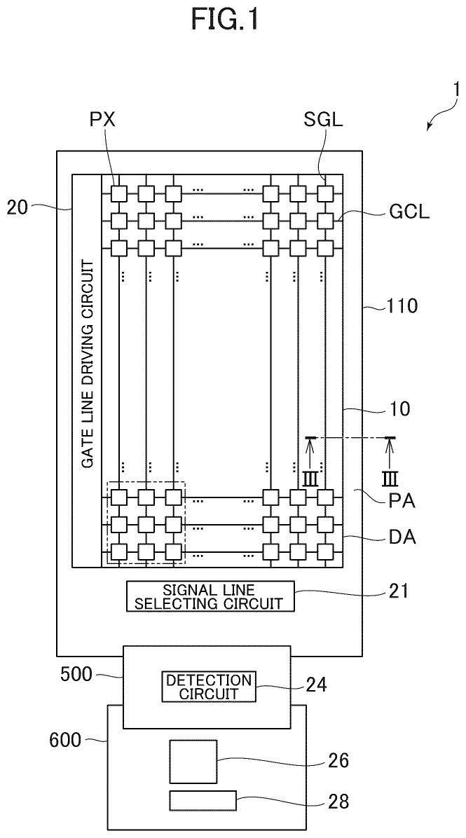

FIG. 1 is a block diagram showing a substrate configuration of a photodetection device according to the first embodiment. As shown in FIG. 1, a photodetection device 1 includes a substrate 110, a sensor unit 10, a gate line driving circuit 20, a signal line selecting circuit 21, a detection circuit 24, a control circuit 26, and a power supply circuit 28.

A control substrate 600 is electrically connected to the substrate 110 via a flexible printed board 500. The flexible printed board 500 includes the detection circuit 24. The control substrate 600 includes the control circuit 26 and the power supply circuit 28. The control circuit 26 is a field programmable gate array (FPGA), for example. The control circuit 26 supplies control signals to the sensor unit 10, the gate line driving circuit 20, and the signal line selecting circuit 21 so as to control the detection operation of the sensor unit 10. The power supply circuit 28 supplies a power supply voltage to the sensor unit 10, the gate line driving circuit 20, and the signal line selecting circuit 21.

The photodetection device 1 includes a detection area DA and a frame area PA. The detection area DA is an area in which the sensor unit 10 is provided. The frame area PA is an area outside the detection area DA where the sensor unit 10 is not provided. In other words, the frame area PA is an area between the edge portion of the detection area DA and the edge portion of the substrate 110.

The sensor unit 10 includes a plurality of pixels PX and receives light from the detection object. The pixels PX are disposed in a matrix in the detection area DA. The pixels PX include light detection sensors, which are photodiodes, and respectively output electric signals corresponding to light irradiating the respective photodiodes. Each pixel PX outputs, to the signal line selecting circuit 21, an electric signal corresponding to the light radiated to the pixel PX as a detection signal Vdet. The photodetection device 1 may be capable of detecting biological data, such as a blood vessel image of a finger and a palm, a pulse wave, a pulse, and a blood-oxygen saturation, based on the detection signal Vdet from each pixel PX. Each pixel PX performs detection in accordance with a gate drive signal Vgcl supplied from the gate line driving circuit 20.

The gate line driving circuit 20 and the signal line selecting circuit 21 are provided in the frame area PA. Specifically, as shown in FIG. 1, the gate line driving circuit 20 is provided in an area of the frame area PA extending along the extension direction of the signal line SGL. The signal line selecting circuit 21 is provided in an area of the frame area PA extending along the extension direction of the gate line GCL, and is provided in an area in the lower side of the substrate 110.

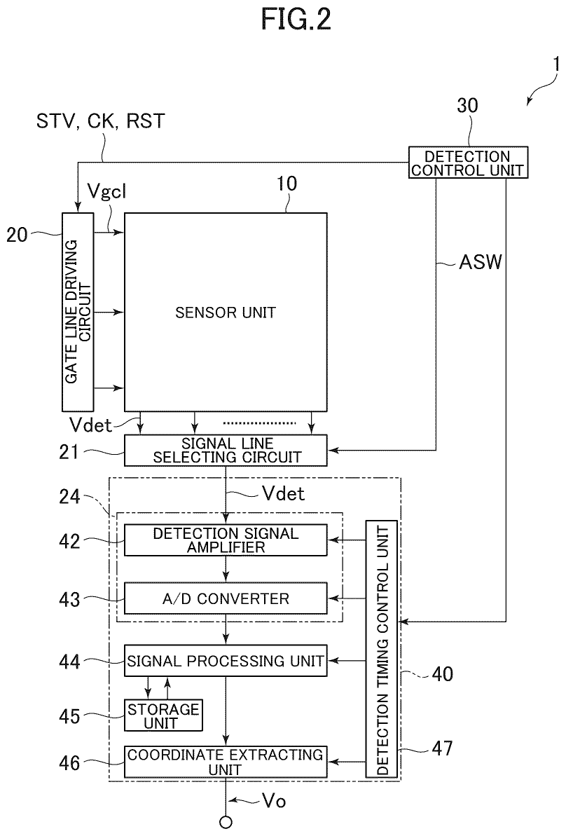

FIG. 2 is a block diagram showing an outline of a circuit configuration of the photodetection device according to the first embodiment. As shown in FIG. 2, the photodetection device 1 includes a detection control unit 30 and a detection unit 40. Some or all of the functions of the detection control unit 30 are included in the control circuit 26. Further, some or all of the functions of the detection unit 40 other than the detection circuit 24 are included in the control circuit 26.

The detection control unit 30 is a circuit that supplies control signals to the gate line driving circuit 20, the signal line selecting circuit 21, and the detection unit 40, and controls these operations. The detection control unit 30 supplies control signals, such as a start signal STV, a clock signal CK, and a reset signal RST, to the gate line driving circuit 20. The detection control unit 30 supplies control signals, such as a selection signal ASW, to the signal line selecting circuit 21. The gate line driving circuit 20 drives the gate line GCL based on the control signals. The gate line driving circuit 20 sequentially or simultaneously selects a plurality of gate lines GCL, and supplies a gate drive signal Vgcl to the selected gate line GCL. In this manner, the gate line driving circuit 20 selects a pixel PX connected to the gate line GCL. The signal line selecting circuit 21 is a switching circuit that sequentially or simultaneously selects a plurality of signal lines SGL. The signal line selecting circuit 21 is a multiplexer, for example. The signal line selecting circuit 21 connects the selected signal line SGL with the detection circuit 24 based on the selection signal ASW supplied from the detection control unit 30. This enables the signal line selecting circuit 21 to output a detection signal Vdet of the pixel PX to the detection unit 40.

The detection unit 40 includes the detection circuit 24, a signal processing unit 44, a storage unit 45, a coordinate extracting unit 46, and a detection timing control unit 47. The detection timing control unit 47 controls the detection circuit 24, the signal processing unit 44, and the coordinate extracting unit 46 to operate in synchronization based on the control signal supplied from the detection control unit 30.

The detection circuit 24 is an analog front end circuit (AFE), for example. The detection circuit 24 is a signal processing circuit having at least functions of a detection signal amplifier 42 and an A/D converter 43. The detection signal amplifier 42 amplifies the detection signal Vdet. The A/D converter 43 converts an analog signal from the detected signal amplifier 42 into a digital signal. The signal processing unit 44 is a logic circuit that detects a predetermined physical quantity entered into the sensor unit 10 based on the output signal of the detection circuit 24. When a detection target, such as a finger and a palm, comes into contact with or is close to the detection surface, the signal processing unit 44 detects unevenness of the surface of the finger and the palm based on the signal from the detection circuit 24. Further, the signal processing unit 44 detects biological data, such as a blood vessel image of a finger and a palm, a pulse wave, a pulse, and a blood-oxygen saturation, based on a signal from the detection circuit 24. The storage unit 45 temporarily stores the signal calculated by the signal processing unit 44. The storage unit 45 may be a random access memory (RAM) or a register circuit, for example. The coordinate extracting unit 46 is a logic circuit that obtains detection coordinates of unevenness of a surface of a finger and a palm, for example, when the signal processing unit 44 detects contact or approach of the finger or the palm. The coordinate extracting unit 46 is a logic circuit that obtains detection coordinates of blood vessels of a finger and a palm, for example. The coordinate extracting unit 46 combines detection signals Vdet from the respective pixels PX of the sensor unit 10 to generate two-dimensional information indicating the shape of the unevenness of the surface of the finger and the palm, for example. The coordinate extracting unit 46 may not calculate the detection coordinates but output the detection signal Vdet as the sensor output Vo.

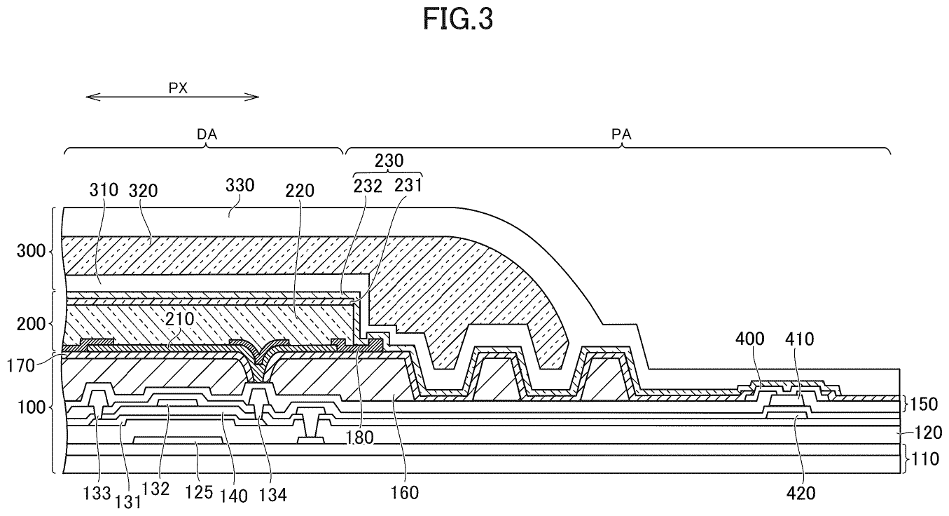

Referring to FIG. 3, the substrate 110 will be described in detail. FIG. 3 is a cross-sectional view of the photodetection device corresponding to the line III-III in FIG. 1. FIG. 3 shows a part of the detection area DA near the edge portion and the entire frame area PA. In FIG. 3, hatching is omitted in some layers to facilitate a view of the cross-sectional structure.

As shown in FIG. 3, the photodetection device 1 includes a lower structure 100 including a thin film transistor TFT, an OPD layer 200 provided on the lower structure 100, a sealing structure 300 provided on the OPD layer 200, and a common line connecting portion 400.

The lower structure 100 includes a substrate 110 and a barrier inorganic layer 120 provided on the substrate 110. For example, the substrate 110 may have a two-layer structure of a glass substrate and a resin substrate provided thereon. The resin substrate may be formed of polyimide, for example. However, the present invention is not limited thereto, and the substrate 110 does not have a glass substrate and may be formed of only a flexible resin substrate. The barrier inorganic layer 120 may have a laminate structure including a plurality of layers. The lower structure 100 may include an additional layer 125 at the position where the thin film transistor TFT is formed.

The thin film transistor TFT includes a semiconductor layer 131, a gate electrode 132, a source electrode 133, and a drain electrode 134. A gate insulating layer 140 is provided between the semiconductor layer 131 and the gate electrode 132. A silicon oxide layer may be used as the gate insulating layer 140. An interlayer insulating layer 150 is formed on the gate electrode 132. The interlayer insulating layer 150 may have a laminate structure of a silicon nitride layer and a silicon oxide layer.

A flattening layer 160 is formed on the interlayer insulating layer 150. The flattening layer 160 may be made of a resin having excellent surface flatness, such as photosensitive acrylic. The flattening layer 160 may be removed at the part that electrically connects the OPD layer 200 and the lower structure 100. The flattening layer 160 may be partially removed in the frame area PA so as to form a bank. The bank may be formed so as to block and prevent the resin material constituting the sealing structure 300 from leaking out of the frame area PA.

An insulating layer 170 may be provided on the flattening layer 160. Further, an inorganic insulating layer 180 made of an inorganic material may be provided on the insulating layer 170 in the detection area DA. Such an inorganic insulating layer 180 may be referred to as a rib, a partition wall, and a bank, for example. The inorganic insulating layer 180 is an inorganic insulating layer formed of silicon nitride, for example. The inorganic insulating layer 180 may also be provided on the pixel electrode 210 included in the OPD layer 200 so as to expose the pixel electrode 210.

The OPD layer 200 is provided with the pixels PX shown in FIG. 1 arranged thereon. The OPD layer 200 includes pixel electrodes 210 provided on the insulating layer 170, an organic photoelectric conversion layer 220 continuously covering the pixel electrodes 210, and a transparent electrode layer 230 provided on the organic photoelectric conversion layer 220. The transparent electrode layer 230 includes a first transparent electrode layer 231 provided on the organic photoelectric conversion layer 220 and a second transparent electrode layer 232 provided on the first transparent electrode layer 231.

The pixel electrodes 210 are formed corresponding to the respective pixels PX and are electrically connected to the drain electrode 134 of the lower structure 100. The organic photoelectric conversion layer 220 functions as a photoelectric conversion layer. In the first embodiment, the organic photoelectric conversion layer 220 is continuously formed on all of the pixel electrodes 210 in the detection area DA. “Continuously” means extends without any discontinuity, and the organic photoelectric conversion layer 220 is formed on all the pixel electrodes 210 in the detection area DA without any discontinuity.

The transparent electrode layer 230 may be referred to as an upper electrode or a common electrode. The first transparent electrode layer 231 and the second transparent electrode layer 232 are common electrodes that are provided to overlap all of the pixels PX of the detection area DA. The second transparent electrode layer 232 is continuously formed on one common line connecting portion 400 to be described later and the first transparent electrode layer 231. The first transparent electrode layer 231 and the second transparent electrode layer 232 may be formed of an indium-based oxide. Among the indium-based oxides, indium-zinc oxide (IZO) may be used.

The first transparent electrode layer 231 and the second transparent electrode layer 232 may be formed of different materials if the material is transparent and conductive. The first transparent electrode layer 231 and the second transparent electrode layer 232 may be formed of the same material. A part of the transparent electrode layer 230 that overlaps the pixel electrodes 210 forms the first transparent electrode layer 231 and is thus thicker than the other part. A part of the detection area DA that overlaps all of the pixel electrode 210 is thicker than a part of the bank portion or a portion that overlaps the common line connecting portion 400 by an amount corresponding to the first transparent electrode layer 231. The transparent electrode layer 230 covering the side surface of the OPD layer 200 does not include the first transparent electrode layer 231 formed therein, and thus is thinner than the part of the transparent electrode layer overlapping the pixel electrodes 210.

The sealing structure 300 includes a first inorganic layer 310 provided on the transparent electrode layer 230, a resin layer 320 provided on the first inorganic layer 310, and a second inorganic layer 330 provided on the resin layer 320. The resin layer 320 may be made of a material having high transmittance and low moisture permeability.

The end portions of the first inorganic layer 310, the resin layer 320, and the second inorganic layer 330 are located in the frame area PA. In particular, the end portion of the second inorganic layer 330 is located near the edge of the substrate 110. The second inorganic layer 330 is in contact with the first inorganic layer 310 in the frame area PA. As described above, the plurality of inorganic layers prevent moisture from entering the organic photoelectric conversion layer 220 from the outside in the sealing structure 300.

The common line connecting portion 400 is provided on the interlayer insulating layer 150 in the frame area PA and connected to the common line 410. The common line 410 supplies a common voltage to the transparent electrode layer 230 via the common line connecting portion 400. As such, the common line connecting portion 400 and the transparent electrode layer 230 need to be electrically connected to each other. The second transparent electrode layer 232 is continuously formed on the pixel electrodes 210 and the common line connecting portion 400, and thus the first transparent electrode layer 231 and the common line connecting portion 400 are electrically connected to each other. A line 420 is provided on the gate insulating layer 140.

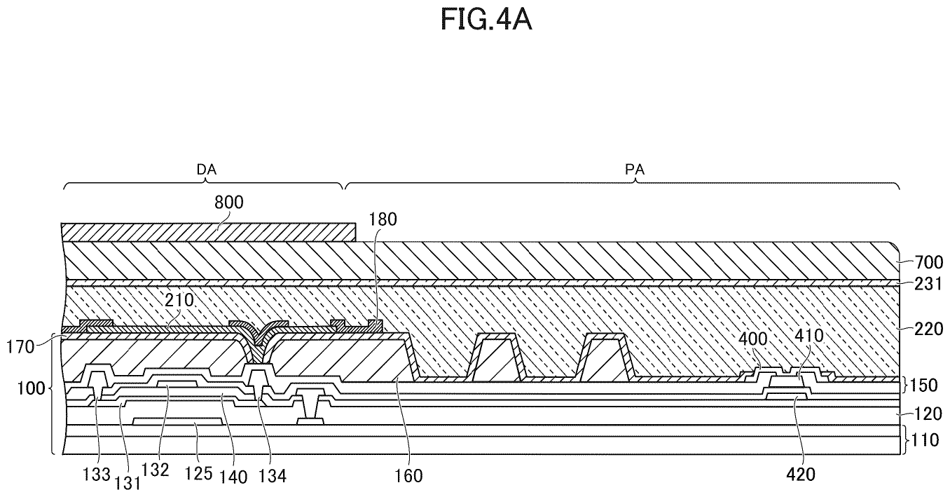

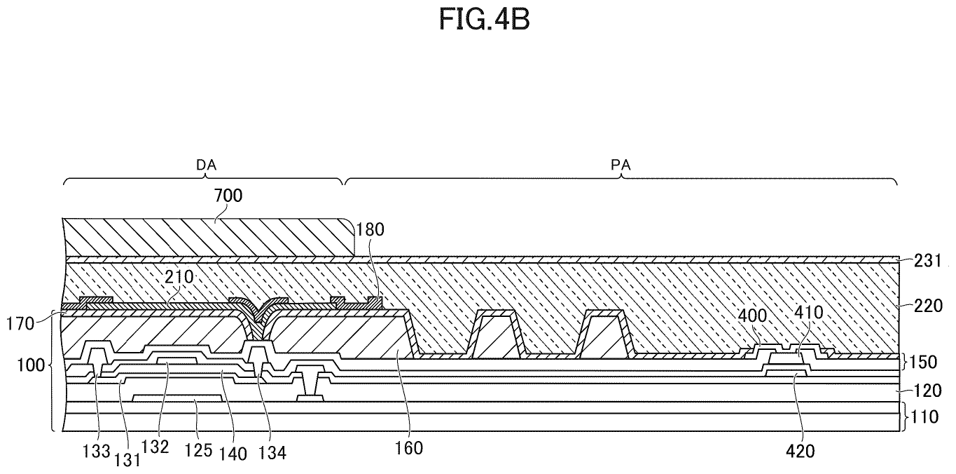

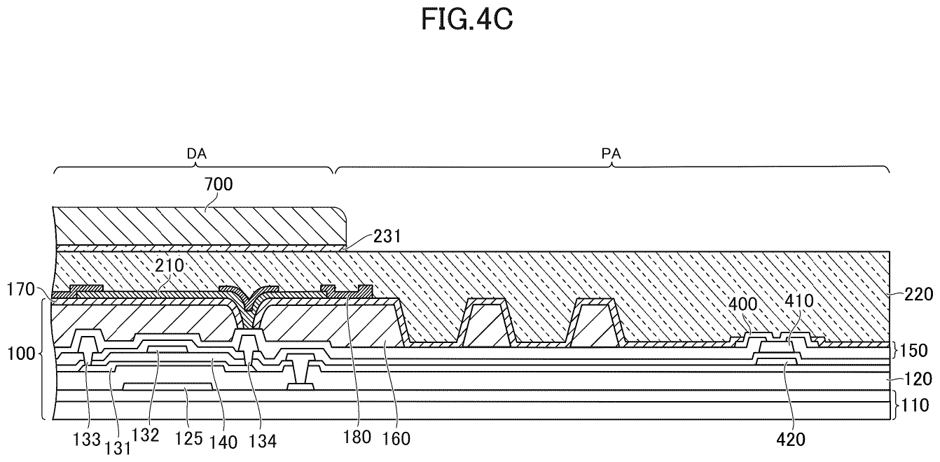

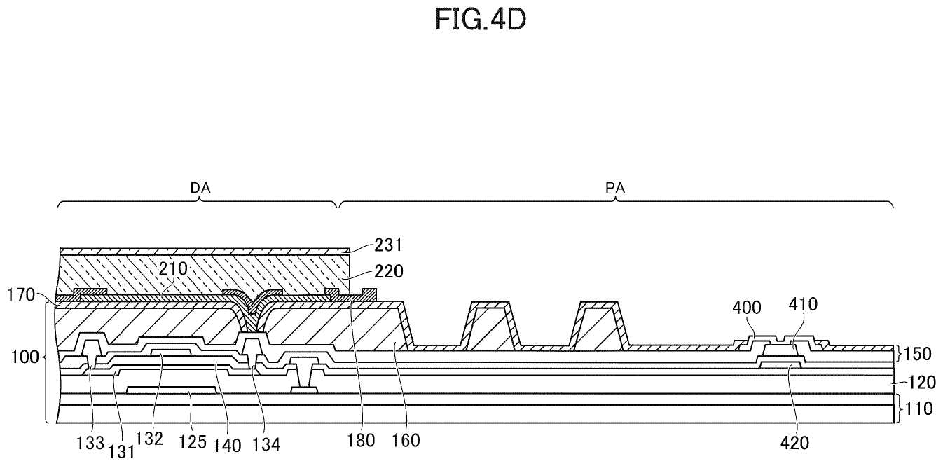

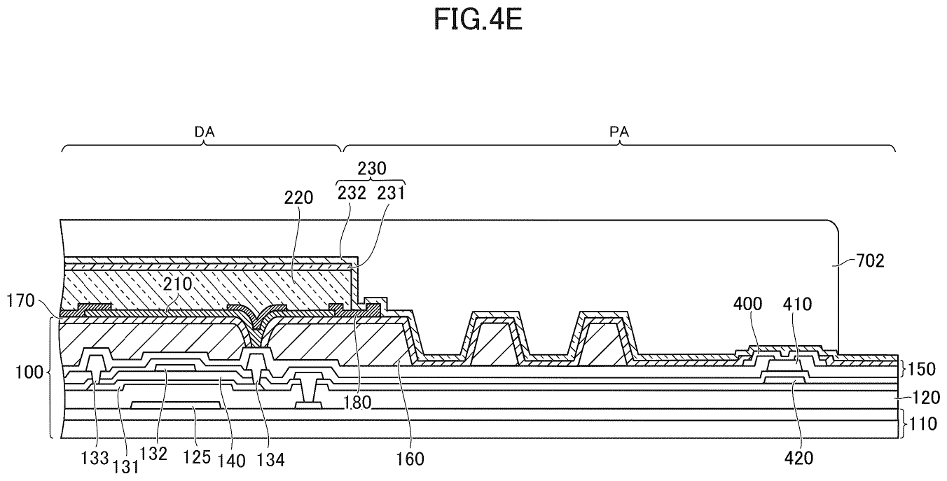

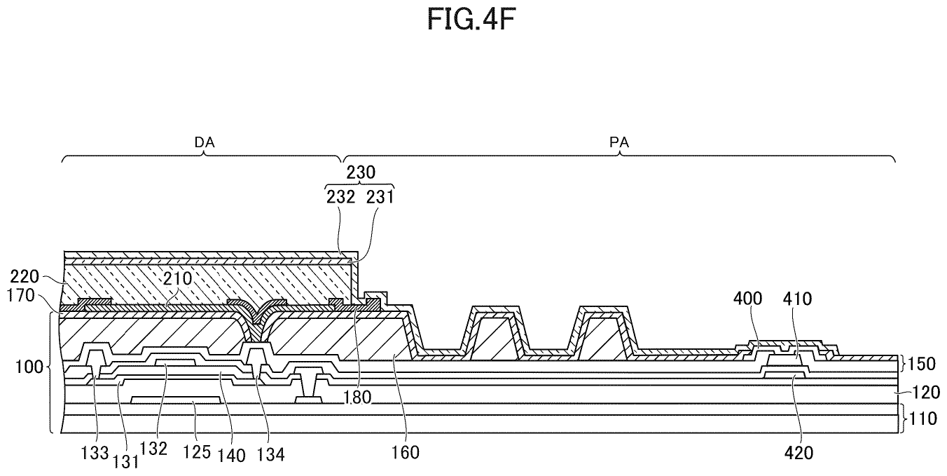

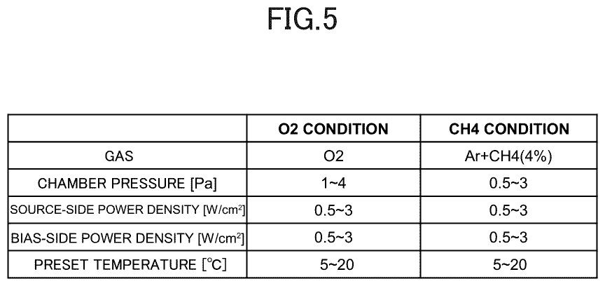

Next, a method of manufacturing the substrate 110 of the first embodiment will be described referring to the drawings. FIGS. 4A to 4F indicate methods for manufacturing the substrate 110 of the first embodiment of the present invention. A cross section taken along the line III-III in FIG. 1 is used as an example. FIG. 5 is a table indicating an example of etching conditions for forming the OPD layer 200 according to the first embodiment. The dry etching of the first embodiment can use reactive ion etching (RIE) or induced coupled plasma (ICP). In the following, assume that the ICP method of the condition shown in FIG. 5 is used.

As shown in FIG. 4A, the lower structure 100, the common line connecting portion 400, the common line 410, and the line 420 are formed on the substrate 110. The substructure 100 is formed by repeating a general photolithographic process a plurality of times. A variety of types of such method are well known, and thus, detailed description thereof will be omitted in this specification.

Subsequently, a plurality of pixel electrodes 210 are formed on the lower structure 100 in the detection area DA. An inorganic insulating layer 180, which serves as a separation wall between the pixel electrodes 210, is then formed. This may also be formed using a common lithographic method. An organic photoelectric conversion layer 220 is then formed in the detection area DA and the frame area PA. For example, the organic photoelectric conversion layer 220 may be formed by a coating using a slit coater.

A first transparent electrode layer 231 is then formed on the organic photoelectric conversion layer 220 in the detection area DA and the frame area PA. A resist 700 is formed on the first transparent electrode layer in the detection area DA and the frame area PA.

A mask 800 is formed so as to overlap all of the pixel electrodes 210 in the detection area DA and not to overlap the common line connecting portion 400. This may also be formed using a common lithographic method.

As shown in FIG. 4B, the resist 700 is patterned by using the mask 800 so as to overlap all of the pixel electrodes 210 in the detection area DA and not to overlap the common line connecting portion 400.

Next, as shown in FIG. 4C, the ICP method using a CH4 gas is used so as to remove a part of the first transparent electrode layer 231 that is not covered with the resist 700. In a case of the dry etching using a CH4 gas, the resist 700 and the organic photoelectric converter layer 220 are hardly etched. As such, after the dry etching, a part of the organic photoelectric conversion layer 220 overlapping with the common line connecting portion 400 is exposed.

Next, as shown in FIG. 4D, the ICP method using an O2 gas is used so as to remove the resist 700 and the part of the organic photoelectric conversion layer 220 that is not covered with the first transparent electrode layer 231. The inorganic insulating material such as SiOx, SiNx, and AlOx and the metal-oxide film such as indium-based oxide are hardly etched by the dry etching using an O2 gas, and thus the insulating layer 170 and the common line connecting portion 400 are hardly etched. In this process, the first transparent electrode layer 231 is formed so as to overlap all of the pixel electrodes 210 and not to overlap with the common line connecting portion 400.

As shown in FIG. 4E, the second transparent electrode layer 232 is formed in the detection area DA and the frame area PA. Subsequently, a resist 702 is continuously formed so as to cover all of the pixel electrodes 210 and the common line connecting portion 400 in the detection area DA. The resist 702 may also be formed using a common lithographic method.

As shown in FIG. 4F, the ICP method using a CH4 gas is used to remove the part of the second transparent electrode layer 232 that is not covered with the resist 702. Subsequently, the resist 702 is removed. In this process, the second transparent electrode layer 232 can be formed to overlap all of the pixel electrodes 210 and also to overlap the common line connecting portion 400.

The first transparent electrode layer 231 is formed of a transparent and conductive material, and thus, even if the first transparent electrode layer is not removed and left on the organic photoelectric conversion layer 220, deterioration of the sensor unit 10 can be reduced. Further, the first transparent electrode layer 231 is used as a protective layer, and this eliminates the process of removing the protective mask to be used for etching the organic photoelectric conversion layer 220.

The first transparent electrode layer 231 may be removed before the second transparent electrode layer 232 is formed. In the case where the first transparent electrode layer 231 is removed, the second transparent electrode layer 232 is continuously formed so as to overlap the organic photoelectric conversion layer 220 instead of the first transparent electrode layer 231 and also to overlap the common line connecting portion 400. When the first transparent electrode layer 231 is removed, if a film remains on the organic photoelectric conversion layer 220, deterioration of the sensor unit 10 can be reduced to a minimum because the first transparent electrode layer 231 is transparent and has conductivity.

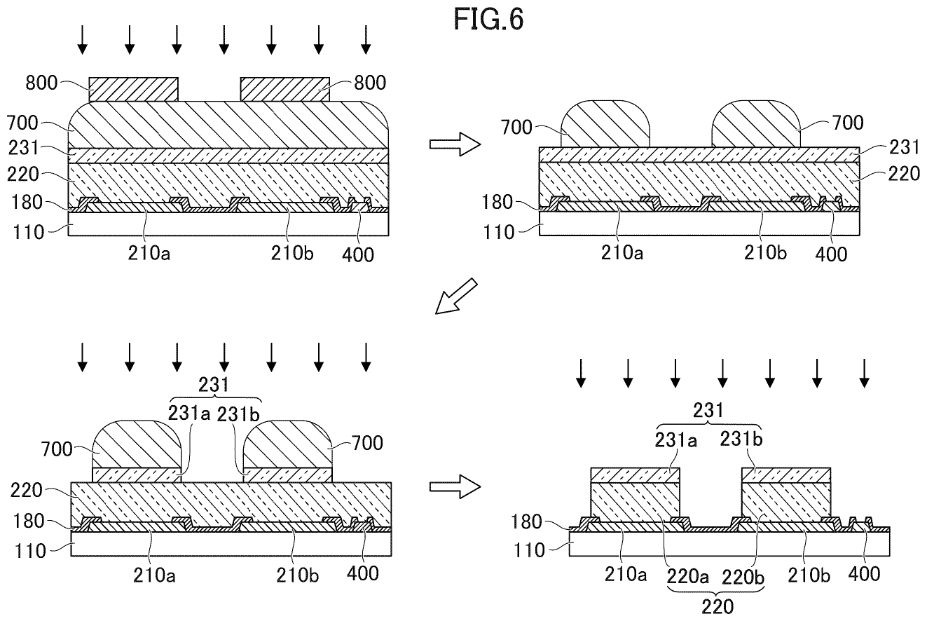

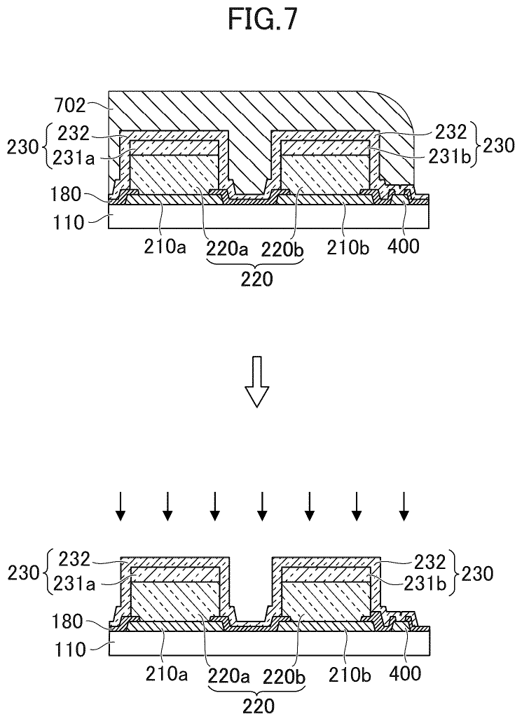

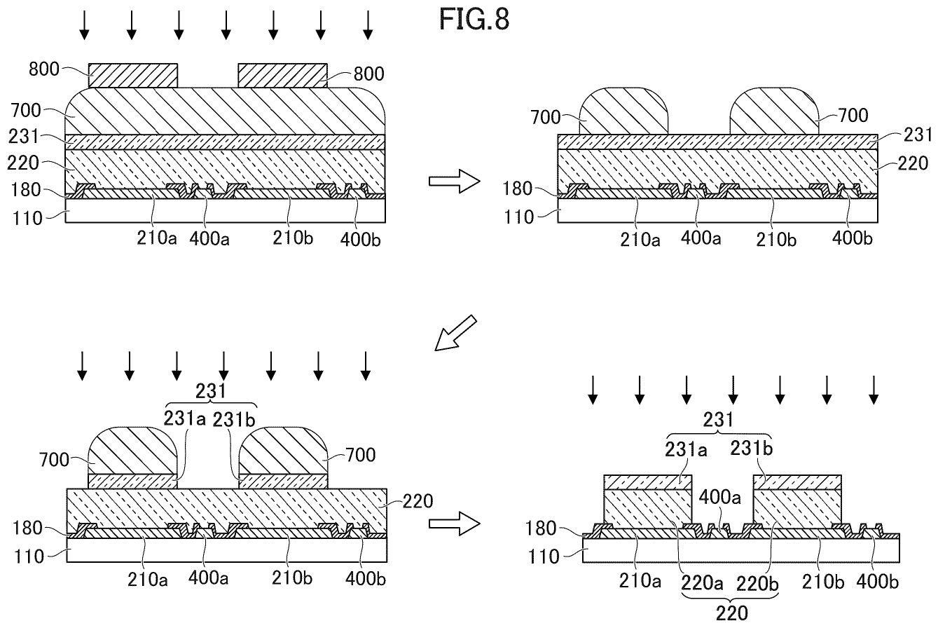

Referring to FIGS. 6 and 7, a manufacturing method of the photodetection device 1 according to the second embodiment will be described. FIGS. 6 and 7 are schematic diagrams showing the manufacturing method according to the second embodiment. The lower structure 100 below the inorganic insulating layer 180 in FIG. 3 is omitted (the same applies to FIGS. 8 to 11 described later).

The second embodiment is different from the first embodiment in that the pixel electrodes 210 and the common line connecting portion 400 are provided in the same layer and the end portion of the common line connecting portion 400 is covered with the inorganic insulating layer 180, where the end portion of the common line connecting portion 400 is covered with the insulating layer 170 in the first embodiment (the same applies to third to fifth embodiments). When the common line connecting portion 400 of the first embodiment is provided, the common line connecting portion 400 may be provided in the same layer as the pixel electrodes 210 similarly to the second embodiment. In the first embodiment, the common line connecting portion 400 of the second embodiment may be provided at a connection with the common line 410. Similarly to the first embodiment, the common line connecting portion 400 covered with the insulating layer 170 may also be provided in the second embodiment.

Similarly to FIG. 4A, a plurality of pixel electrodes 210 and a common line connecting portion 400 are formed on the substrate 110. For convenience of explanation, one of the pixel electrodes 210 is referred to as a pixel electrode 210a, and another one is referred to as a pixel electrode 210b. As shown in the upper left side of FIG. 6, the organic photoelectric converter layer 220 is continuously formed on the pixel electrode 210a, the pixel electrode 210b, and the common line connecting portions 400 over the entire surface of the substrate. A first transparent electrode layer 231 is then formed on the organic photoelectric conversion layer 220. Further, a resist 700 is formed on the first transparent electrode layer 231. Masks 800 are separately formed on the resists 700 so as to overlap the pixel electrode 210a and the pixel electrode 210b.

As shown in the upper right side of FIG. 6, the resist 700 is patterned using the masks 800. The masks 800 are formed so as to respectively overlap he pixel electrode 210a and the pixel electrode 210b, and thus, the resist 700 is similarly formed so as to overlap each of the pixel electrode 210a and the pixel electrode 210b.

As shown in the lower left side of FIG. 6, the ICP method using a CH4 gas is used to remove the first transparent electrode layer 231 other than the part that is not covered with the resist 700. In this process, the first transparent electrode layer 231 is separated into a first individual transparent electrode 231a overlapping the pixel electrode 210a and a first individual transparent electrode 231b overlapping the pixel electrode 210b. The first transparent electrode layer 231 is formed separately so as to overlap each of the pixel electrodes 210 and not to overlap with the common line connecting portion 400.

As shown in the lower right part of FIG. 6, the ICP method using an O2 gas is used to remove the resists 700 and a part of the organic photoelectric converter layer 220 that are not covered with the first individual transparent electrode 231a and the first individual transparent electrode 231b. In this process, the organic photoelectric conversion layer 220 is separated into an organic photoelectric conversion layer 220a overlapping pixel electrode 210a and an organic photoelectric conversion layer overlapping the pixel electrode 210b. This is because the organic photoelectric conversion layer 220 on each pixel electrodes 210 is protected by the first transparent electrode layer that is not etched by the O2 gas. A part of the organic photoelectric conversion layer 220 that is not covered with the first transparent electrode layer 231 is removed, and the inorganic insulating layer 180 and the common line connecting portion 400 between the pixel electrode 210a and the pixel electrode 210b are exposed.

As shown in the upper part of FIG. 7, a second transparent electrode layer 232 is formed on the entire surface of the substrate. Subsequently, a resist 702 is continuously formed so as to cover the pixel electrode 210a, the pixel electrode 210b, and the common line connecting portion 400.

Next, as shown in the lower part of FIG. 7, the ICP method using a CH4 gas is used to remove the part of the second transparent electrode layer 232 that is not covered with the resist 702. The resist 702 is then removed. In this process, the second transparent electrode layers 232 continuously overlapping the pixel electrode 210a, the pixel electrode 210b, and the common line connecting portion 400 can be formed. The first individual transparent electrode 231a and the second transparent electrode layer 232 function as the upper electrode of the OPD layer 200 in the pixel electrode 210a, and the first individual transparent electrode 231b and the second transparent electrode layer 232 function as the upper electrode of the OPD layer 200 in the pixel electrode 210b.

The second embodiment is different from the first embodiment in that the organic photoelectric converter layer 220 is formed with each of pixel electrodes 210 so as to overlap the corresponding one of the pixel electrodes 210. In this manner, the organic photoelectric conversion layer 220 is separately formed on each of the pixel electrodes 210, and the leakage current between the pixel electrodes 210 can be thereby prevented.

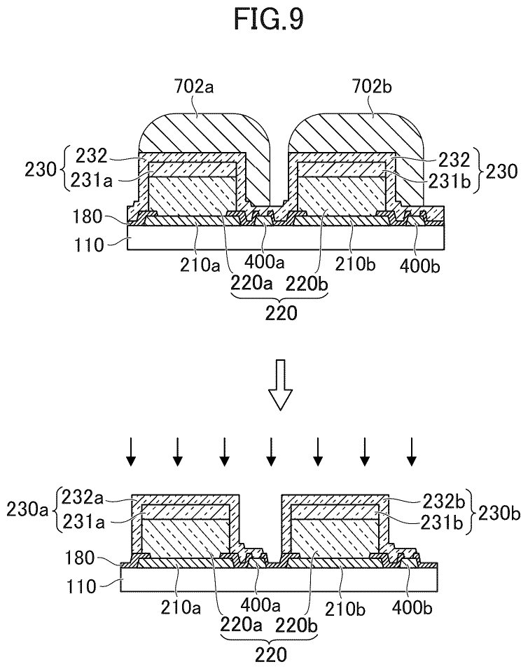

Referring to FIGS. 8 and 9, a manufacturing method of the photodetection device 1 according to the third embodiment will be described. FIGS. 8 and 9 are schematic diagrams showing the manufacturing method according to the third embodiment.

First, as shown in the upper left side of FIG. 8, a pixel electrode 210a, a common line connecting portion 400a, a pixel electrode 210b, and a common line connecting portion 400b are formed on the substrate 110. One pixel electrode 210 and one common line connecting portion 400 are formed so as to be adjacent to each other. The organic photoelectric conversion layer 220 is continuously formed on the entire surface of the substrate 110. The first transparent electrode layer 231 is then formed on the organic photoelectric conversion layer 220. Further, a resist 700 is formed on the first transparent electrode layer 231. Masks 800 are separately formed on the resist 700 so as to overlap the pixel electrode 210a and the pixel electrode 210b.

As shown in the upper right side of FIG. 8, the resist 700 is patterned using the masks 800. The masks 800 are formed so as to respectively overlap the pixel electrode 210a and the pixel electrode 210b, and thus, the resists 700 is similarly formed so as to respectively overlap the pixel electrode 210a and the pixel electrode 210b.

As shown in the lower left side of FIG. 8, the ICP method using a CH4 gas is used to remove the part of the first transparent electrode layer 231 that is not covered with the resist. In this process, the first transparent electrode layer 231 is separated into a first individual transparent electrode 231a overlapping the pixel electrode 210a and a first individual transparent electrode 231b overlapping the pixel electrode 210b. The first transparent electrode layer 231 is formed separately so as to overlap each of the pixel electrodes 210 and not to overlap with the common line connecting portion 400. The first transparent electrode layer 231 is formed so as to overlap each of the pixel electrodes 210 and not to overlap with the common line connecting portions 400.

As shown in the lower right part of FIG. 8, the ICP method using an O2 gas is used to remove the resists 700 and the part of the organic photoelectric conversion layer 220 that are not covered with the first individual transparent electrode 231a and the first individual transparent electrode 231b. In this process, the organic photoelectric conversion layer 220 is separated into an organic photoelectric conversion layer 220a overlapping the pixel electrode 210a and an organic photoelectric conversion layer 220b overlapping the pixel electrode 210b. This is because the organic photoelectric conversion layer 220 on each pixel electrodes 210 is protected by the first transparent electrode layer 231 that is not etched by the O2 gas. A part of the organic photoelectric conversion layer 220 that is not covered with the first transparent electrode layer 231 is removed, and the inorganic insulating layer 180 between the pixel electrode 210a and the pixel electrode 210b, the common line connecting portion 400a, and the common line connecting portion 400b are exposed.

As shown in the upper part of FIG. 9, a second transparent electrode layer 232 is formed on the entire surface of the substrate. Subsequently, a resist 702a covering the pixel electrode 210a and the common line connecting portion 400a and a resist 702b covering the pixel electrode 210b and the common line connecting portion 400b are separately formed.

As shown in the lower part of FIG. 9, the ICP method using a CH4 gas is used to remove the part of the second transparent electrode layer 232 that is not covered with the resist 702. The resist 702 is then removed. In this process, the second transparent electrode layer 232 is separated into a second individual transparent electrode 232a on the first individual transparent electrode 231a and a second individual transparent electrode 232b on the first individual transparent electrode 231b. The first individual transparent electrode 231a and the second individual transparent electrode 232a function as the common electrode of the OPD layer 200 in the pixel electrode 210a, and the first individual transparent electrode 231b and the second transparent electrode layer 232b function as the common electrode of the OPD layer 200 in the pixel electrode 210b.

The third embodiment is different from the second embodiment in that one pixel electrode 210 and one common line connecting portion 400 are formed to be adjacent to each other, and each second transparent electrode layer 232 is formed so as to overlap one pixel electrode 210 and one common line connecting portion 400. One common line connecting portion 400 is formed to be adjacent to one pixel electrode 210, and thus the same potential can be stably supplied to a plurality of pixel electrodes 210.

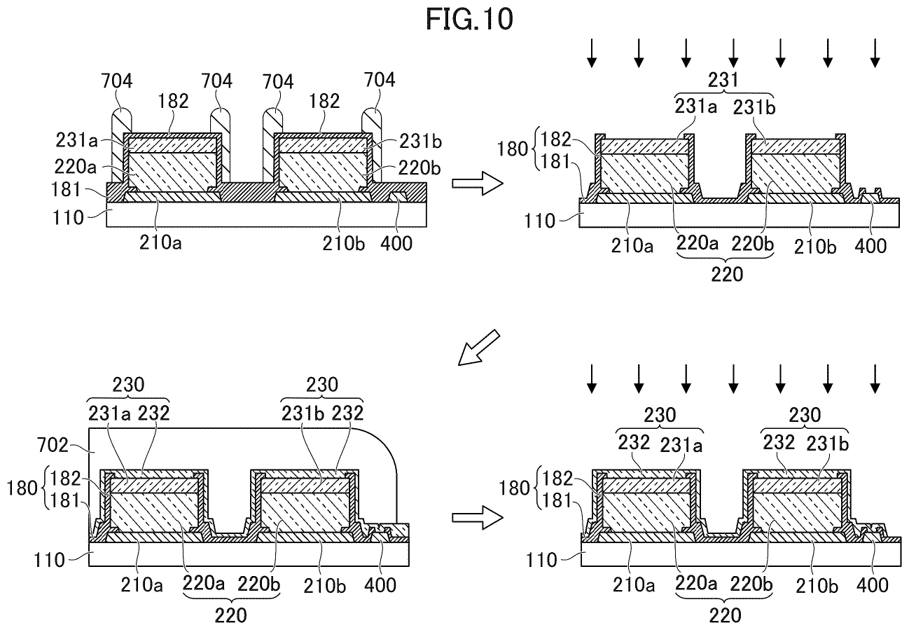

Referring to FIG. 10, a manufacturing method of the photodetection device 1 according to the fourth embodiment will be described. FIG. 10 is a schematic diagram showing a manufacturing method according to the fourth embodiment. The manufacturing method according to the fourth embodiment is the same as that in FIG. 6 of the second embodiment up to a step of forming the first transparent electrode layer 231. For convenience of explanation, one of the pixel electrodes 210 is referred to as a pixel electrode 210a, and another one is referred to as a pixel electrode 210b.

After removing the resist 700 and the part of the organic photoelectric conversion layer 220 that is not covered with the first transparent electrode layer 231, the fourth embodiment further includes a step of forming a rib 182 that covers the side surfaces of the organic photoelectric conversion layer 220 and the first transparent electrode layer 231. After the first transparent electrode layer 231 is formed (see the lower right part of FIG. 6), as shown in the upper left part of FIG. 10, the rib 182 made of the same material as the inorganic insulating layer 181 is continuously formed on the inorganic insulating layer 181, the first individual transparent electrode 231a, the first individual transparent electrode 231b, and the common line connecting portion 400. The inorganic insulating layer 181 corresponds to the inorganic insulating layer 180 in the lower right part of FIG. 6. Subsequently, resists 704 are formed on the rib 182 and at both ends of each pixel electrode 210.

As shown in the upper right part of FIG. 10, the ICP method using a CH4 gas is used to remove the part of the rib 182 that is not covered with the resist 704. The resist 704 is then removed. The part of the rib 182 that is not covered with the resist 704 is removed, and the upper surface of the first transparent electrode layer 231 is exposed. In this process, the ribs 182 covering the side surfaces of the first transparent electrode layer 231 and the organic photoelectric conversion layer 220 can be formed.

As shown in the lower left part of FIG. 10, the second transparent electrode layer 232 is formed on the entire surface of the substrate. Subsequently, a resist 702 is continuously formed so as to cover the pixel electrode 210a, the pixel electrode 210b, and the common line connecting portion 400.

Next, as shown in the lower right part of FIG. 10, the ICP method using a CH4 gas is used to remove the part of the second transparent electrode layer 232 that is not covered with the resist 702. The resist 702 is then removed. In this process, while the ribs 182 covering the side surfaces of the first transparent electrode layer 231 and the organic photoelectric conversion layer 220 are provided, the second transparent electrode layer 232 continuously overlapping the pixel electrode 210a, the pixel electrode 210b, and the common line connecting portion 400 can be formed.

The fourth embodiment is different from the second embodiment in that the ribs 182 are formed on the side surfaces of the first transparent electrode layer 231 and the organic photoelectric conversion layer 220. The ribs 182 made of an inorganic material are formed so as to cover the side surfaces of the organic photoelectric conversion layer 220, and whereby a leakage current from the side surface of the organic photoelectric conversion layer 220 can be prevented.

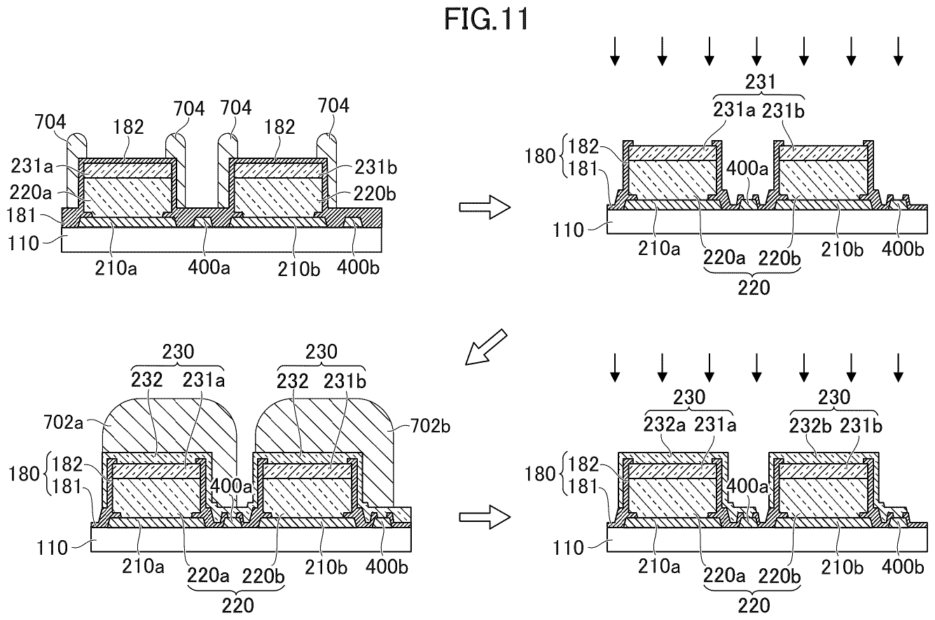

Referring to FIG. 11, a manufacturing method of the photodetection device 1 according to the fifth embodiment will be described. FIG. 11 is a schematic diagram showing a manufacturing method according to the fifth embodiment. The manufacturing method according to the fifth embodiment is the same as that in FIG. 8 of the third embodiment up to a step of forming the first transparent electrode layer 231. The plurality of pixel electrodes 210 formed on the substrate 110 are referred to as pixel electrodes 210a and pixel electrodes 210. The plurality of common line connecting portions 400 formed on the substrate 110 are referred to as common line connecting portions 400a and common line connecting portions 400b.

After removing the resist 700 and the part of the organic photoelectric conversion layer 220 that is not covered with the first transparent electrode layer 231, the fifth embodiment further includes a step of forming a rib 182 that covers the side surfaces of the organic photoelectric conversion layer 220 and the first transparent electrode layer 231. After the first transparent electrode layer 231 is formed (see the lower right part of FIG. 8), as shown in the upper left part of FIG. 11, the rib 182 made of the same material as the inorganic insulating layer 181 is continuously formed on the inorganic insulating layer 181, the first individual transparent electrode 231a, the first individual transparent electrode 231b, the common line connecting portions 400a, and the common line connecting portion 400b. The inorganic insulating layer 181 corresponds to the inorganic insulating layer 180 on the lower right part of FIG. 8. Subsequently, resists 704 are formed on the rib 182 and at both ends of each pixel electrode 210.

As shown in the upper right part of FIG. 11, the part of the rib 182 that is not covered with the resist 704 is removed using the ICP method using a CH4 gas. The resist 704 is then removed. The part of the rib 182 that is not covered with the resist 704 is removed, and the upper surface of the first transparent electrode layer 231 is exposed. In this process, the ribs 182 covering the side surfaces of the first transparent electrode layer 231 and the organic photoelectric conversion layer 220 can be formed.

As shown in the lower left part of FIG. 11, the second transparent electrode layer 232 is formed on the entire surface of the substrate. Subsequently, a resist 702a covering the pixel electrode 210a and the common line connecting portion 400a and a resist 702b covering the pixel electrode 210b and the common line connecting portion 400b are separately formed.

As shown in the lower right part of FIG. 11, the ICP method using a CH4 gas is used to remove the part of the second transparent electrode layer 232 that is not covered with the resist 702. The resist 702 is then removed. In this process, while the ribs 182 covering the side surfaces of the first transparent electrode layer 231 and the organic photoelectric conversion layer 220 are provided, the second individual transparent electrode 232a and the second individual transparent electrode 232b can be separately formed.

The fifth embodiment is different from the third embodiment in that the ribs 182 are formed on the side surfaces of the first transparent electrode layer 231 and the organic photoelectric conversion layer 220. The ribs 182 made of an inorganic material are formed so as to cover the side surfaces of the organic photoelectric conversion layer 220, and whereby a leakage current from the side surface of the organic photoelectric conversion layer 220 can be prevented.

The present invention is not limited to the embodiment described above, and various modifications can be made. For example, the configurations described in the embodiment can be replaced by substantially the same configurations, configurations that exhibit the same operational effect, or configurations that can achieve the same object.

What is claimed is:

1. A manufacturing method of a photodetection device comprising:
forming a lower structure;
forming one or more common line connecting portions and one or more pixel electrodes on the lower structure;
continuously forming an organic photoelectric conversion layer on the one or more common line connecting portions and the one or more pixel electrodes;
forming a first transparent electrode layer continuously on the one or more common line connecting portions and the one or more pixel electrodes;
forming a resist on the first transparent electrode layer which is patterned so as to overlap with the one or more pixel electrode and not to overlap with the one or more common line connecting portion;
removing a part of the first transparent electrode layer that is not covered with the resist;
removing the resist and a part of the organic photoelectric conversion layer that is not covered with the first transparent electrode layer so as to expose the one or more common line connecting portion; and
forming a second transparent electrode layer continuously so as to overlap with the organic photoelectric conversion layer or the first transparent electrode layer as well as the one or more common line connecting portion.

2. The manufacturing method according to claim 1, wherein
the second transparent electrode layer is formed so as to overlap with the first transparent electrode layer and the one or more common line connecting portion.

3. The manufacturing method according to claim 1, further comprising removing the first transparent electrode layer after exposing the one or more common line connecting portion, wherein
the second transparent electrode layer is formed so as to overlap with the organic photoelectric conversion layer and the one or more common line connecting portion.

4. The manufacturing method according to claim 1, wherein
the resist is formed on the first transparent electrode layer with each of the pixel electrodes so as to overlap a corresponding one of the pixel electrodes.

5. The manufacturing method according to claim 4, wherein
two or more pixel electrodes and one common line connecting portion are formed, and
the second transparent electrode layer is formed so as to overlap with the organic photoelectric conversion layer or the first transparent electrode layer and the one common line connecting portion.

6. The manufacturing method according to claim 4, wherein
one pixel electrode and one common line connecting portion are formed so as to be adjacent to each other, and
the second transparent electrode layer is formed so as to overlap with the one pixel electrode and the one common line connecting portion.

7. The manufacturing method according to claim 4, further comprising forming a rib so as to cover a side surface of the organic photoelectric conversion layer before forming the second transparent electrode layer and after exposing the one or more common line connecting portion.

8. The manufacturing method according to claim 1, wherein
the first transparent electrode layer and the second transparent electrode layer is formed of a same material.

9. The manufacturing method according to claim 1, wherein
the first transparent electrode layer is made of indium-based oxide.

10. The manufacturing method according to claim 1, wherein
the first transparent electrode layer is made of indium-zinc oxide (IZO).

11. The manufacturing method according to claim 1, wherein
a part of the first transparent electrode layer that is not covered with the resist is removed by an inductively coupled plasma method using a gas containing CH4.

12. The manufacturing method according to claim 1,
the resist and a part of the organic photoelectric conversion layer that is not covered with the first transparent electrode layer is removed using an inductively coupled plasma method using a gas containing O2 so as to expose the one or more common line connecting portions.

13. A photodetection device comprising:
a lower structure;
one or more common line connecting portions and one or more pixel electrodes provided on the lower structure;
an organic photoelectric conversion layer that is provided so as to overlap with the one or more pixel electrodes and not to overlap with the one or more common line connecting portions; and
a transparent electrode layer that is provided so as to overlap with the organic photoelectric conversion layer and the one or more common line connecting portion, wherein
a part of the transparent electrode layer that overlaps with the one or more pixel electrodes is thicker than other parts.

14. The photodetection device according to claim 13, wherein
the transparent electrode layer includes:
a first transparent electrode layer that is provided on the organic photoelectric conversion layer so as to overlap with the one or more pixel electrode and not to overlap with the one or more common line connecting portion; and
a second transparent electrode layer that is provided so as to overlap with the first transparent electrode layer and the one or more common line connecting portion.
